(19) United States
(12) Patent Application Publication
(10) Pub. No.: US 2024/0290809 A1
(43) Pub. Date: Aug. 29, 2024

(54) SOLID-STATE IMAGE SENSOR, MANUFACTURING METHOD THEREOF, AND ELECTRONIC DEVICE

(71) Applicant: SONY SEMICONDUCTOR SOLUTIONS CORPORATION, KANAGAWA (JP)

(72) Inventor: BO MA, KANAGAWA (JP)

(21) Appl. No.: 18/576,852

(22) PCT Filed: Jul. 21, 2021
(86) PCT No.: PCT/JP2021/027268

§ 371 Date: Jan. 5, 2024

(51) Int. Cl. H01L 27/146

(52) U.S. Cl. CPC H01L 27/1463; H01L 27/1462; H01L 27/14643; H01L 27/14694

(57) ABSTRACT

The present disclosure relates to a solid-state image sensor configured to be capable of suppressing dark currents in a solid-state image sensor including a compound semiconductor and a manufacturing method thereof, and an electronic device. A solid-state image sensor includes a photoelectric conversion layer containing a compound semiconductor, pixel electrodes that take out electric charges generated in the photoelectric conversion layer for each pixel, and a pixel separation portion disposed between the pixel electrodes of each pixel. The technique of the present disclosure can be applied to a solid-state image sensor that photoelectrically converts light with wavelengths within the visible region and the short infrared region.

### TECHNICAL FIELD

The present disclosure relates to a solid-state image sensor and a manufacturing method thereof, and an electronic device, and particularly, to a solid-state image sensor configured to be capable of suppressing dark currents in a solid-state image sensor including a compound semiconductor and a manufacturing method thereof, and an electronic device.

### BACKGROUND ART

Conventionally, solid-state image sensors including compound semiconductors, such as InGaAs, as photoelectric conversion layers have been known (for example, see Patent Literature 1). In such solid-state image sensors, P-type diffusion regions including P-type impurities, such as Zn (zinc), dispersed therein are formed for each pixel as pixel electrodes for reading out signal discharges generated in a photoelectric conversion portion.

### CITATION LIST

### Patent Literature

[PTL 1]
WO 2017/150167

### SUMMARY

### Technical Problem

However, there is a concern about the deterioration of dark currents due to the strong electric field generated by the P-type diffusion regions as pixel electrodes.

The present disclosure has been made in view of such circumstances and is intended to suppress dark currents in the solid-state image sensors including compound semiconductors.

### Solution to Problem

A solid-state image sensor of the first aspect of the present disclosure includes a photoelectric conversion layer containing a compound semiconductor, pixel electrodes that take out electric charges generated in the photoelectric conversion layer for each pixel, and a pixel separation portion disposed between the pixel electrodes of each pixel.

A method for manufacturing a solid-state image sensor of the second aspect of the present disclosure includes forming a pixel separation portion at a pixel boundary between a light incidence surface and an opposite surface of a photoelectric conversion layer containing a compound semiconductor, and forming a pixel electrode that take out an electric charge generated in the photoelectric conversion layer for each pixel inside the pixel separation portion.

An electronic device of the third aspect of the present disclosure includes a solid-state image sensor that includes a photoelectric conversion layer containing a compound semiconductor, pixel electrodes that take out electric charges generated in the photoelectric conversion layer for each pixel, and a pixel separation portion disposed between the pixel electrodes of each pixel.

In the first and third aspects of the present disclosure, a photoelectric conversion layer containing a compound semiconductor, pixel electrodes that take out electric charges generated in the photoelectric conversion layer for each pixel, and a pixel separation portion disposed between the pixel electrodes of each pixel is disposed.

In the second aspect of the present disclosure, a pixel separation portion is formed at a pixel boundary between a light incidence surface and an opposite surface of a photoelectric conversion layer containing a compound semiconductor, and pixel electrodes that take out an electric charge generated in the photoelectric conversion layer for each pixel is formed inside the pixel separation portion.

The solid-state image sensor and electronic device may be independent devices or may be modules incorporated into other devices.

### BRIEF DESCRIPTION OF DRAWINGS

FIG. 1 is a cross-sectional diagram of a first embodiment of a pixel array region according to the present disclosure.

FIG. 2 is a diagram for explaining the potential of a pixel in FIG. 1.

FIG. 3 is a diagram to explain the method for manufacturing the pixel of FIG. 1.

FIG. 4 is a cross-sectional diagram of a second embodiment of a pixel array region according to the present disclosure.

FIG. 5 is a diagram illustrating a schematic configuration of a solid-state image sensor to which the technique of the present disclosure is applied.

FIG. 6 is a diagram illustrating a pixel circuit in FIG. 5.

FIG. 7 is a block diagram illustrating a configuration example of an image-capturing device as an electronic device to which the present technique is applied.

FIG. 8 is a diagram illustrating an image sensor.

FIG. 9 is a block diagram illustrating an example of a schematic configuration of a vehicle control system.

FIG. 10 is an explanatory diagram illustrating an example of the installation positions of a vehicle's exterior information-detecting unit and an image-capturing unit.

### DESCRIPTION OF EMBODIMENTS

Modes for embodying the technique of the present disclosure (hereinafter referred to as embodiments) will be described below with reference to the accompanying drawings. Description will be given in the following order.
1. First Embodiment of Pixel Array Region
2. Method of Manufacturing Pixel
3. Second Embodiment of Pixel Array Region
4. Overall Configuration Example of Solid-State Image Sensor
5. Examples of Application to Electronic Devices
6. Exemplary Application to Moving Body

In the drawings referred to in the following description, the same or similar portions will be denoted by the same or similar reference signs, and redundant descriptions will be omitted. The drawings are schematic, and relationships between thicknesses and plan view dimensions, ratios of thicknesses of respective layers, and the like differ from the actual ones. In addition, drawings may include portions where dimensional relationships and ratios differ between the drawings in some cases.

In addition, it is to be understood that definitions of directions, such as upward and downward, in the following description are merely definitions provided for the sake of brevity and are not intended to limit the technical ideas of the present disclosure. For example, when an object is observed after being rotated by 90 degrees, up-down is converted into and interpreted as left-right, and when an object is observed after being rotated by 180 degrees, up-down is interpreted as being inverted.

### 1. First Embodiment of Pixel Array Region

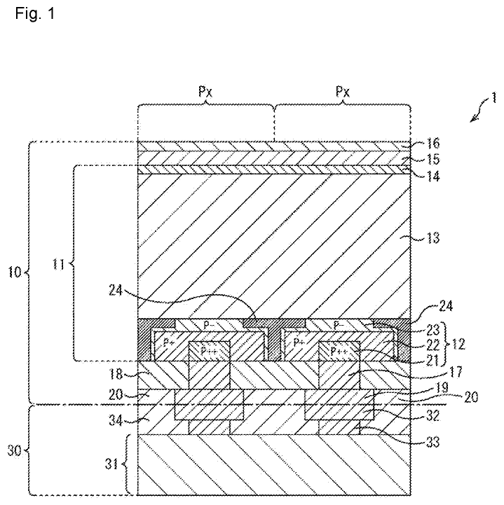

FIG. 1 is a sectional diagram of a first embodiment of a pixel array region according to the present disclosure.

The pixel array region 1 is configured so that pixels Px are disposed two-dimensionally in a matrix, and the pixel array region 1 illustrated in FIG. 1 indicates a cross-sectional diagram of two pixels Px aligned horizontally or vertically. This pixel array region 1 is adopted, for example, as a pixel array region of a solid-state image sensor that photoelectrically converts light with wavelengths within the visible region (for example, 380 nm or higher and shorter than 780 nm) and the short infrared region (for example, 780 nm or higher and shorter than 2400 nm).

The pixel array region 1 is configured by laminating a sensor substrate 10 and a circuit board 30. The dash-dotted line of FIG. 1 illustrates a joined surface between the sensor substrate 10 and the circuit board 30.

The sensor substrate 10 is a substrate that photoelectrically converts light incident on the upper surface (the surface opposite to the circuit board 30 side) of FIG. 1 to generate signal discharges. The circuit board 30 is a substrate on which the readout circuit that reads out the signal charges generated by sensor substrate 10 is formed.

The sensor substrate 10 has a semiconductor layer 11. For example, the semiconductor layer 11 is configured by laminating, from the circuit board 30 side, a pixel electrode (a pixel electrode layer) 12, a photoelectric conversion layer 13, and a barrier layer 14.

The pixel electrode 12 is a semiconductor layer that functions as a lower electrode (a first electrode) of the two electrodes that sandwich the photoelectric conversion layer 13 above and below and is for reading out the signal charges generated in the photoelectric conversion layer 13 for each pixel Px to the circuit board 30. The upper surface, which is one surface of the pixel electrode 12, is connected to the photoelectric conversion layer 13, and the lower surface, which is the other surface on the opposite side, is connected to the contact electrode 17. The pixel electrode 12 is formed by a diffused region of a P-type impurity formed by diffusing a P-type impurity, such as Zn (zinc), in the same compound semiconductor material as the photoelectric conversion layer 13 or a compound semiconductor material with a larger band gap. As the same compound as the photoelectric conversion layer 13, for example, InGaAs (indium gallium arsenide) or the like may be used as will be described later. For example, as a compound semiconductor material with a larger band gap than the compound semiconductor material of the photoelectric conversion layer 13, InP (indium phosphide) may be used.

The impurity concentration of the pixel electrode 12 formed in the P-type diffusion region is formed so as to gradually decrease from the contact electrode 17 side toward the photoelectric conversion layer 13 side. For example, the impurity concentration of the pixel electrode 12 has a high concentration region 21 with a first concentration (P++) that is the highest concentration, a middle concentration region 22 with a second concentration (P+) that is lower than the first concentration, and a low concentration region 23 with a third concentration (P−) that is lower than the second concentration from the side closer to the contact electrode 17. For example, the thickness of the pixel electrode 12 is about 100 nm to 500 nm.

At the pixel boundary portion of the same layer as the pixel electrodes 12, a pixel separation portion 24 is formed, and the pixel electrodes 12 are electrically separated for each pixel Px. Although illustration is omitted, when the pixel array region 1 is viewed in plan view, the pixel separation portion 24 is formed in a grid pattern and disposed to surround rectangular pixel regions. This enables the signal charges generated in the photoelectric conversion layer 13 to be read out for each pixel. The pixel separation portion 24 may be formed by a metal film, such as titanium (Ti), tungsten (W), or titanium nitride (TiN), or an oxide film, such as silicon oxide (SiO₂).

The photoelectric conversion layer 13 is a layer that absorbs light with a predetermined wavelength and generates signal charges and, for example, is constituted of a compound semiconductor material, such as a III-V semiconductor. As illustrated in FIG. 1, this photoelectric conversion layer 13 is disposed on the entire surface of the pixel array region 1 in common to all pixels Px. Examples of compound semiconductor materials constituting the photoelectric conversion layer 13 include InGaAs (indium gallium arsenide), InAsSb (indium arsenide antimony), InAs (indium arsenide), InSb (indium antimony), PbS (lead sulfide), PbSe (lead selenide), GeAu (germanium gold), HgCdTe (mercury cadmium tellurium), and the like. The photoelectric conversion layer 13 may be constituted of Ge (germanium). For example, the photoelectric conversion layer 13 is configured to photoelectrically convert light with wavelengths from the visible region to the short infrared region. For example, the thickness of the photoelectric conversion layer 13 is about 3000 nm to 10000 nm.

The barrier layer 14 is a semiconductor layer that is disposed to be connected to the upper electrode 15 on the light incidence surface side and prevents the backflow of signal charges generated by the photoelectric conversion layer 13, and, for example, is disposed on the entire surface of the pixel array region 1 in common to all pixels Px. The barrier layer 14 is disposed between and in contact with the photoelectric conversion layer 13 and the upper electrode 15. The barrier layer 14 is a region in which electric charges discharged from the upper electrode 15 move and, for example, is composed of a compound semiconductor containing an N-type impurity. For example, when holes are read out from the pixel electrode 12 as signal charges, electrons move into this barrier layer 14. For example, N-type InP (indium phosphide) may be used as the compound semiconductor material of the barrier layer 14. The thickness of the barrier layer 14 may be, for example, about 10 nm to 400 nm, and preferably 100 nm or less. By reducing the thickness of the barrier layer 14, the light absorbed by the barrier layer 14 is reduced, and the sensitivity of the photoelectric conversion layer 13 can be improved.

On the upper side (light incidence surface side) of the barrier layer 14, the upper electrode 15 is disposed, for example, as an electrode common to the pixels Px. The upper electrode 15 is the upper side electrode (second electrode) of the two electrodes that sandwich the photoelectric conversion layer 13 above and below. The upper electrode 15 discharges charges that are not used as signal charges among the charges generated in the photoelectric conversion layer 13 (cathode). For example, when holes are read out from the pixel electrode 12 as signal charges, electrons can be discharged through this upper electrode 15. For example, a predetermined bias voltage Va will be applied to this upper part electrode 15. The upper electrode 15 is composed of a conductive film that can transmit incident light, such as infrared light, and indium tin oxide (ITO) or ITiO (In₂O₃—TiO₂) can be used, for example.

On the upper side of the upper electrode 15, a passivation film 16 is formed. Examples of materials used for the passivation film 16 include silicon nitride (SiN), hafnium oxide (HfO₂), aluminum oxide (Al₂O₃), zirconium oxide (ZrO₂), tantalum oxide (Ta₂Ta₅), titanium oxide (TiO₂), and the like. The passivation film 16 also functions as an anti-reflection film.

On the circuit board 30 side of the semiconductor layer 11, a contact electrode 17 and a passivation film 18 are formed in the same layer. The contact electrode 17 is at least connected to the high concentration region 21 of the pixel electrode 12 on the upper surface on the semiconductor layer 11 side and connected to the pad electrode 19 on the lower surface on the circuit board 30 side. Similar to the passivation film 16 described above, the passivation film 18 is formed of silicon nitride (SiN), hafnium oxide (HfO₂), aluminum oxide (Al₂O₃), zirconium oxide (ZrO₂), tantalum oxide (Ta₂Ta₅), titanium oxide (TiO₂), or the like. For example, the pad electrode 19 is formed of copper (Cu) in the interlayer insulation film 20. The pad electrode 19 is electrically connected to a pad electrode 32 of the circuit board 30 by metal joining, such as Cu—Cu joining. The interlayer insulation film 20 is also connected to the interlayer insulation film 34 on the circuit board 30 side by oxide film joining in a planar region other than the Cu—Cu joined region.

For example, the contact electrode 17 is made of a single material of any of titanium (Ti), tungsten (W), titanium nitride (TiN), platinum (Pt), gold (Au), germanium (Ge), palladium (Pd), zinc (Zn), nickel (Ni), or aluminum (Al), or an alloy containing at least one of them. The contact electrode 17 may be a single film of such constituent materials, or may be a laminated film in which two or more of the constituent materials are combined. For example, the contact electrode 17 is composed of a laminated film of titanium and tungsten.

For example, the interlayer insulation film 20 is composed of an inorganic insulation material. Examples of inorganic insulation materials include silicon nitride (SiN), aluminum oxide (Al₂O₃), silicon oxide (SiO₂), hafnium oxide (HfO₂), and the like.

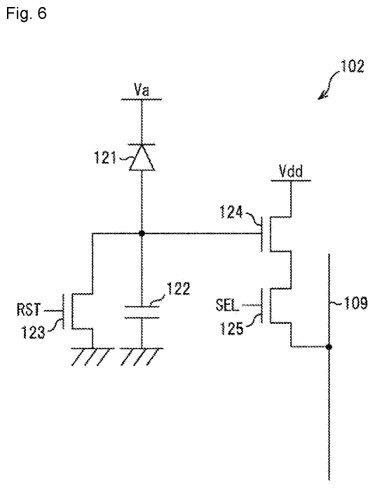

For example, the circuit board 30 has a semiconductor substrate 31 made of a single crystal material, such as a single crystal silicon (Si). On the semiconductor substrate 31, a readout circuit of pixels Px, specifically, a capacitive element, a reset transistor, an amplification transistor, a selection transistor, and the like are formed. Details of the pixel circuit will be described later with reference to FIG. 6. It is noted that the readout circuit of the pixel Px may partly be formed on the sensor substrate 10 side.

On the sensor substrate 10 side of the semiconductor substrate 31, a pad electrode 32 and a contact electrode 33 electrically connecting the pad electrode 32 and the semiconductor substrate 31 are formed, and the layer from the joint surface to the semiconductor substrate 31 other than the pad electrode 32 and the pad electrode 32 are filled with an interlayer insulation film 34.

As the material of the contact electrode 33, the same type of materials for the contact electrode 17 described above may be used. However, the materials for the contact electrode 33 may differ from those for the contact electrode 17. For example, the interlayer insulation film 34 is composed of an inorganic insulation material. Examples of inorganic insulation materials include silicon nitride (SiN), aluminum oxide (Al₂O₃), silicon oxide (SiO₂), hafnium oxide (HfO₂), and the like.

The operation of the pixels Px will be described. For example, in the pixels Px, when light with wavelengths within the visible region and the infrared region is incident on the photoelectric conversion layer 13 through the passivation film 16 and upper part electrode 15, this light is photoelectrically converted in the photoelectric conversion layer 13. At this time, when a predetermined voltage is applied to, for example, the contact electrode 17, a potential gradient occurs in the photoelectric conversion layer 13, and either charge (e.g., a hole) of a pair of a hole and an electron generated by photoelectric conversion moves to the pixel electrode 12 as a signal charge and is collected from the pixel electrode 12 to the contact electrode 17. This signal charge moves to the pixel circuit of the semiconductor substrate 31 through the pad electrodes 19 and 32 and is read out for each pixel Px.

For example, each pixel Px in the pixel array region 1 with the above pixel structure receives light with wavelengths within the visible region and the short infrared region and outputs the obtained signal.

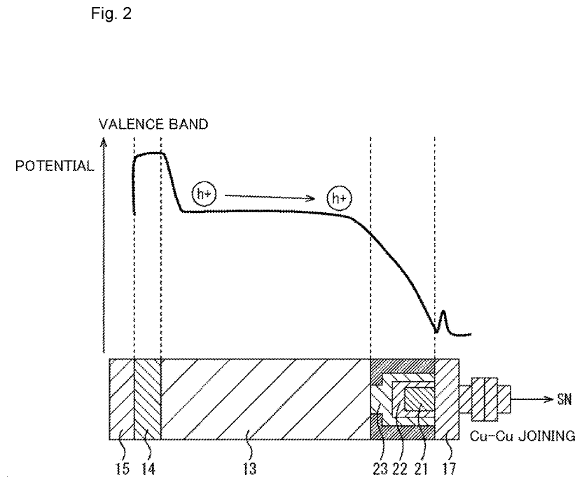

In pixels Px of the pixel array region 1, the P-type impurity concentration of the pixel electrode 12 formed so as to be separated for each pixel is formed so as to decrease step by step from the contact electrode 17 side toward the photoelectric conversion layer 13 side. This allows a gradual formation of the electric field at the pixel electrode 12, as illustrated in the potential diagram in FIG. 2, thereby suppressing dark currents. In other words, a strong electric field occurs when the P-type diffusion region of the pixel electrode 12 is formed evenly at a high impurity concentration, thereby causing the deterioration of dark currents, but such dark currents caused by a strong electric field can be prevented.

In the pixel Px, the pixel separation portion 24 is disposed at the pixel boundaries in the same layer as the pixel electrode 12 to electrically separate the pixel electrodes 12 for each pixel Px. This allows the electric characteristics for each pixel Px to be separated, and pixel separation can be improved.

As described below, in the P-type impurity diffusion step of the pixel electrode 12, the P-type impurity is diffused not only in the depth direction of the sensor substrate 10 (longitudinal direction in the figure) but also in the lateral direction. However, the placement of the pixel separation portion 24 at the pixel boundaries produces the effect of preventing excessive diffusion in the lateral direction and can prevent leakage to adjacent pixels.

### 2. Method of Manufacturing Pixel

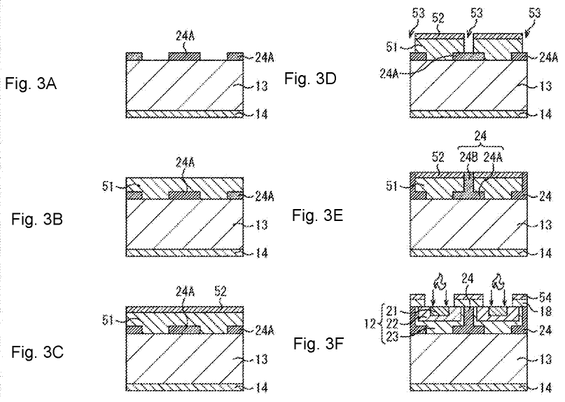

A method of manufacturing the pixel Px of FIG. 1 will be described with reference to FIG. 3.

At first, as illustrated as Ain FIG. 3, the pixel separation plane portion 24A that is a part of the pixel separation portion 24 and spreads in the plane direction is patterned around the pixel boundaries on the surface opposite to the surface on which the barrier layer 14 of the photoelectric conversion layer 13 is formed. For example, the material of the pixel separation plane portion 24A is an oxide film, such as silicon oxide (SiO₂), but may be a metal film, such as titanium (Ti) or tungsten (W).

Next, as illustrated as B in FIG. 3, a compound semiconductor layer 51 is formed by crystal growth on the upper surface of the pixel separation plane portion 24A and the upper surface of the photoelectric conversion layer 13, where the pixel separation plane portion 24A is not patterned. The material of the compound semiconductor layer 51 may be the same semiconductor material as in the photoelectric conversion layer 13, and, for example, may be InGaAs (indium gallium arsenide). For example, the formation of the compound semiconductor layer 51 may be achieved by using a combination of organometallic vapor phase epitaxy (MOVPE) and microchannel epitaxy (MCE).

Next, as illustrated as C in FIG. 3, a compound semiconductor layer 52 with a larger band gap than the compound semiconductor material of the photoelectric conversion layer 13 is formed by crystal growth on the upper surface of the compound semiconductor layer 51. Examples of materials used for the compound semiconductor layer 52 include N-type InP (indium phosphide).

Next, as illustrated as D in FIG. 3, a trench 53 is formed by opening the pixel boundary portions of the compound semiconductor layers 51 and 52 until the pixel separation plane portion 24A is exposed.

Then, as illustrated as E in FIG. 3, a pixel separation wall 24B that is a part of the pixel separation portion 24 and separates the compound semiconductor layers 51 and 52 of each pixel Px is formed by filling the formed trench 53 with an oxide film (SiO₂) that is the same material as the pixel separation plane portion 24A. This pixel separation wall 24B and the pixel separation plane portion 24A formed previously constitute the pixel separation portion 24.

Next, as illustrated as F in FIG. 3, a passivation film 18 is formed in a region other than the region in which the contact electrode 17 (FIG. 1) is formed, and a mask 54 of an oxide film, etc., is formed on the upper surface of the passivation film 18. Then, a P-type impurity, such as Zn (zinc), is doped in the compound semiconductor layers 51 and 52 from the opening region of the mask 54 using heat diffusion. As a result, the pixel electrodes 12 are formed in pixel regions inside the pixel separation portion 24 in the plane direction. P-type impurities are diffused isotropically in heat diffusion. Thus, the high concentration region 21, middle concentration region 22, and low concentration region 23 are formed from the side closer to the opening region of the mask 54. A semiconductor layer 11 composed of the pixel electrode 12, photoelectric conversion layer 13, and barrier layer 14 is completed in this way. The F in FIG. 3 corresponds to the state reversing FIG. 1.

As described above, the semiconductor layer 11 of the sensor substrate 10 can be formed, and the impurity concentration of the pixel electrode 12 is formed so as to decrease step by step from the contact electrode 17 side toward the photoelectric conversion layer 13 side.

In the formation step of the pixel electrode 12, if it were tried to diffuse a P-type impurity thickly in the depth direction by heat diffusion, the P-type impurities are also widely diffused in the lateral direction. However, the diffusion in the lateral direction is prevented by the pixel separation portion 24. That is, the placement of the pixel separation portion 24 at the pixel boundaries can prevent excessive diffusion in the lateral direction and prevent leakage to adjacent pixels.

Furthermore, forming the pixel separation portion 24 to have a substantially T-shaped cross-sectional structure consisting of the pixel separation plane portion 24A and the pixel separation wall 24B improves the uniformity of the impurity concentration of the low concentration region 23 in the region opened at the pixel separation plane portion 24A and improves the flatness of the surface of the pixel electrode 12 in contact with the photoelectric conversion layer 13. This reduces the variation in the characteristics of dark currents.

### 3. Second Embodiment of Pixel Array Region

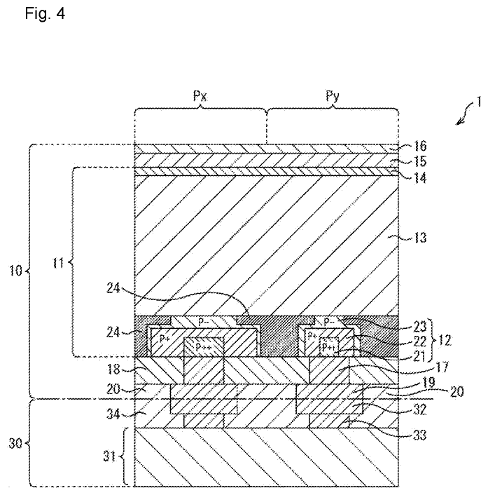

FIG. 4 is a cross-sectional diagram of a second embodiment of a pixel array region according to the present disclosure.

In FIG. 4, portions corresponding to those in the first embodiment described above are denoted by the same reference numerals and signs, and descriptions of such portions will be omitted as appropriate.

The pixel array region 1 of the second embodiment illustrated in FIG. 4 differs in that the pixels Px and pixels Py are arranged alternately in the horizontal and vertical directions, respectively, and is common in other respects. The pixel array region 1 of the second embodiment is configured such that pixels Px and pixels Py are arranged in a checkerboard pattern, respectively.

The pixel Px has a configuration similar to that in the first embodiment. The pixel Px reads out the signal charges (e.g., holes) generated in the photoelectric conversion layer 13, passing through the pixel electrode 12, and collected by the contact electrode 17 and outputs the signal charges as pixel signals. In contrast, the pixel Py is a drain pixel that discharges the signal charges (e.g., holes) generated in the photoelectric conversion layer 13, passing through the pixel electrode 12, and collected by the contact electrode 17 as unnecessary charges without outputting them as pixel signals.

Comparing the pixel Py and pixel Px as drain pixels, a large pixel separation portion 24 is formed in the plane direction in the pixel Py, and, as a result, the plane region of the pixel electrode 12 is smaller than the pixel electrode 12 of the pixel Px. That is, the pixel Px differs from the pixel Py in the formed regions of the pixel electrode 12 and pixel separation portion 24 in the planar direction.

According to the pixel array region 1 of the second embodiment configured as above, a pixel separation portion 24 is provided as in the first embodiment, and the impurity concentration of the pixel electrode 12 is formed so as to gradually decrease from the contact electrode 17 side toward the photoelectric conversion layer 13 side. This allows the electric field of the pixel electrode 12 to be formed gently in the substrate depth direction, thereby suppressing dark currents. Furthermore, the pixel separation portion 24 improves pixel separation. Moreover, in the second embodiment, alternately arranging the pixel Py, which is a drain pixel that does not output pixel signals, and the pixel Px, which is a normal pixel that outputs pixel signals, decreases crosstalk.

The pixel array region 1 of the second embodiment may be manufactured by a similar method to that in the first embodiment explained in FIG. 3.

Suppose a method for manufacturing a pixel array region in which pixels Py and pixels Px are arranged alternately if the pixel separation portion 24 is not formed. If the pixel separation portion 24 is not formed, two-time processing (diffusion step) is necessary because the plane regions of the pixel electrode 12 differ between the pixel Py and pixel Px, and it is necessary to form different opened regions and to differentiate the degree of diffusion between the pixel Py and pixel Px.

In contrast, in the pixel array region 1 of the second embodiment, by forming the pixel separation portion 24, the pixel separation portion 24 can block the diffusion of P-type impurities in the lateral direction. Thus, there is no need to worry about differences in the degree of diffusion of P-type impurities in the lateral direction, and only one-time processing (diffusion step) is needed. That is, the pixel array region 1 of the second embodiment can reduce the steps and also improve diffusion controllability in the process.

### Modification

In the pixel Px and pixel Py described above, the pixel separation portion 24 is formed to have a substantially T-shaped cross-sectional structure consisting of the pixel separation plane portion 24A and the pixel separation wall 24B. However, the pixel separation portion 24 may be formed only by a pixel separation wall 24B in the depth direction (longitudinal direction) while omitting the pixel separation plane portion 24A spreading in the planar direction. The pixel separation wall 24B is formed such that the depth (height) thereof be the same as or deeper than the depth of the pixel electrode 12. The effect described above can also be exhibited in this case because the pixel electrode 12 of each pixel (pixel Px or pixel Py) can be separated.

In the pixel Px and pixel Py described above, only the passivation film 16 is formed on the upper side of the upper electrode 15, which is the side of a light incidence surface. Meanwhile, a color filter layer that transmits either R (red), G (green), or B (blue) light (wavelength light) may be installed in a predetermined array, such as a Bayer layout. Furthermore, an on-chip lens may be formed on the upper surface of the passivation film 16 or the color filter layer.

### 4. Overall Configuration Example of Solid-State Image Sensor

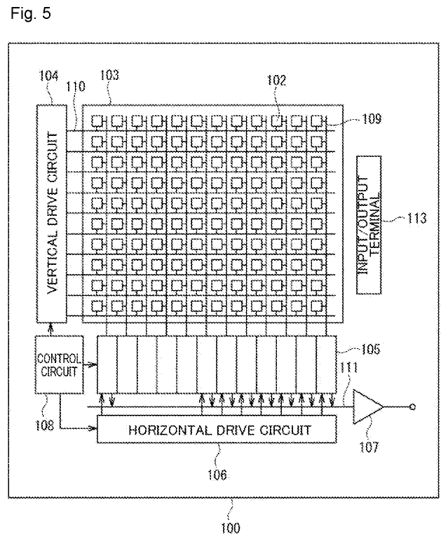

FIG. 5 is a schematic configuration of a solid-state image sensor to which the technique of the present disclosure is applied.

The solid-state image sensor 100 of FIG. 5 is configured by having a pixel array region 103 with a plurality of pixels 102 and a peripheral circuit region formed therearound. The peripheral circuit region includes a vertical drive circuit 104, a column signal processing circuit 105, a horizontal drive circuit 106, an output circuit 107, a control circuit 108, and the like.

As a configuration of the pixel array region 103 in which a plurality of pixels 102 are two-dimensionally arranged in a matrix, the configuration of the pixel array region 1 according to the first embodiment illustrated in FIG. 1 and the configuration of the pixel array region 1 according to the second embodiment illustrated in FIG. 4 are adopted. When the pixel array region 103 is configured by the first embodiment of the pixel array region 1, the pixel array region 103 has the pixel Px of FIG. 1 as the pixel 102. Meanwhile, when the pixel array region 103 is configured by the second embodiment of the pixel array region 1, the pixels Px and pixels Py of FIG. 4 are alternately arranged in the horizontal and perpendicular directions, respectively, in the pixel array region 103 to form the pixels 102. A specific circuit configuration of the pixel 102 will be described with reference to FIG. 6.

The control circuit 108 receives input clocks and data instructing an operation mode and the like and outputs data such as internal information of the solid-state image sensor 100. In other words, in response to a vertical synchronizing signal, a horizontal synchronizing signal, and a master clock signal, the control circuit 108 generates clock signals or control signals to be used as a standard for operation by the vertical drive circuit 104, the column signal processing circuit 105, the horizontal drive circuit 106, and other elements. The control circuit 108 outputs the generated clock signals or control signals to the vertical drive circuit 104, the column signal processing circuit 105, the horizontal drive circuit 106, and other elements.

The vertical drive circuit 104 includes, for example, a shift register, and selects a prescribed pixel drive line 110 and supplies a pulse for driving the pixels 102 to the selected pixel drive line 110 to drive the pixels 102 on a row-basis. In other words, the vertical drive circuit 104 selectively scans pixels 102 in the pixel array region 103 on a row-basis in the vertical direction sequentially and supplies a pixel signal based on signal charges generated according to the amount of received light in the photoelectric conversion portion of the pixels 102 to the column signal processing circuits 105 through a vertical signal line 109.

One column signal processing circuit 105 is arranged for each column of the pixels 102 and performs signal processing such as noise cancellation on a signal outputted from the pixels 102 corresponding to one row for each column. For example, the column signal processing circuits 105 perform signal processing, such as correlated double sampling (CDS) for canceling out fixed pattern noise unique to the pixels and AD conversion.

The horizontal drive circuit 106 is configured by, for example, a shift register, and sequentially selects each of the column signal processing circuits 105 by sequentially outputting horizontal scan pulses and outputs pixel signals from each of the column signal processing circuits 105 to the horizontal signal line 111.

The output circuit 107 performs signal processing on signals sequentially supplied from each column signal processing circuit 105 through the horizontal signal line 111 and outputs the processed signals. For example, the output circuit 107 may perform only buffering in some cases or may perform black level adjustment, column variation compensation, and various kinds of digital signal processing in other cases. An input/output terminal 113 exchanges signals with the outside.

The solid-state image sensor 100 configured as above is a CMOS image sensor called a column AD type sensor, in which one column signal processing circuit 105 that performs CDS processing and AD conversion processing is arranged for each pixel column. Furthermore, the solid-state image sensor 100 with the configuration of the pixel array region 1 described above as the pixel array region 103 is, for example, a CMOS image sensor that outputs a captured image obtained by receiving light with wavelengths within the visible region and the short infrared region.

The solid-state image sensor 100 adopting the configuration of the pixel array region 1 described above suppresses dark currents in each pixel 102 and can create a high-quality captured image.

FIG. 6 shows a pixel circuit of each pixel 102 of the solid-state image sensor 100.

Each pixel 102 includes a photoelectric conversion portion 121, a capacitance element 122, a reset transistor 123, an amplification transistor 124, and a selection transistor 125.

For example, the photoelectric conversion portion 121 is composed of a compound semiconductor, such as InGaAs, and generates electric charges (signal charges) according to the amount of light received. A predetermined bias voltage Va is applied to the photoelectric conversion portion 121. For example, this photoelectric conversion portion 121 corresponds to the photoelectric conversion layer 13 of FIG. 1. For example, the photoelectric conversion portion 121 is formed on the sensor substrate 10 of FIG. 1, and the capacitance element 122, reset transistor 123, amplification transistor 124, and selection transistor 125 are formed on the circuit board 30 of FIG. 1.

The capacitance element 122 accumulates electric charges generated in the photoelectric conversion portion 121. The capacitance element 122 may be configured to include at least one of, for example, a PN junction capacitance, a MOS capacitance, or a wiring capacitance.

When the reset transistor 123 is turned on in response to a reset signal RST, the charges accumulated in the capacitance element 122 are discharged to a source (ground), thereby resetting the potential of the capacitance element 122.

The amplification transistor 124 outputs pixel signals according to the accumulated potential of the capacitance element 122. That is, the amplification transistor 124 constitutes a source follower circuit with a load MOS (not illustrated) as a constant current source connected via the vertical signal line 109, and pixel signals indicating a level according to the charges accumulated in the capacitance element 122 is outputted from the amplification transistor 124 to the column signal processing circuit 105 via the selection transistor 125.

The selection transistor 125 is turned on when a pixel 102 is selected in response to a selection signal SEL, and the pixel signal of the pixel 102 is outputted to the column signal processing circuit 105 via the vertical signal line 109. Each signal line through which the selection signal SEL, and reset signal RST are transmitted corresponds to the pixel drive line 110 in FIG. 5.

### 5. Examples of Application to Electronic Devices

The technique of the present disclosure (present technique) is not limited to an application to a solid-state image sensor. In other words, the present technique can be generally applied to electronic devices using solid-state image sensors in image-capturing portions (photoelectric conversion portions) such as image-capturing devices, including a digital still camera and a video camera, a mobile terminal device with an image-capturing function, and a copy machine having a solid-state image sensor in an image reading unit. The solid-state image sensor may be formed as a one-chip or may be formed as a module in which an image-capturing unit and a signal processing unit or an optical system are collectively packaged and which has an image-capturing function.

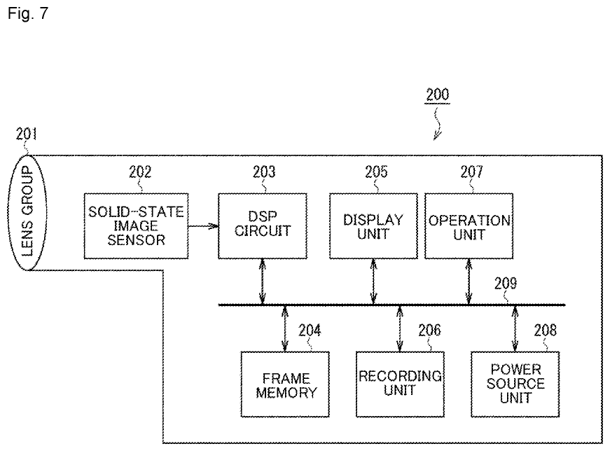

FIG. 7 is a block diagram illustrating a configuration example of an image-capturing device as an electronic device to which the present technique is applied.

An image-capturing device 200 of FIG. 7 includes an optical unit 201 including a lens group and the like, a solid-state image sensor (image-capturing device) 202 adopting the configuration of the solid-state image sensor 100 of FIG. 5, and a digital signal processor (DSP) circuit 203 that is a camera signal processing circuit. The image-capturing device 200 also includes a frame memory 204, a display unit 205, a recording unit 206, an operation unit 207, and a power source unit 208. The DSP circuit 203, the frame memory 204, the display unit 205, the recording unit 206, the operation unit 207, and the power source unit 208 are connected to each other via a bus line 209.

The optical unit 201 captures incident light (image light) from a subject and forms an image on an image-capturing surface of the solid-state image sensor 202. The solid-state image sensor 202 converts an amount of incident light formed on the image-capturing surface by the optical unit 201 into electrical signals for each pixel and outputs the electrical signals as pixel signals. As this solid-state image sensor 202, a solid-state image sensor which has the configuration of the solid-state image sensor 100 of FIG. 5, that is, the pixel array region 1 of FIG. 1 or FIG. 4 as the pixel array region 103 and in which dark currents are suppressed.

The display unit 205 is constituted by a panel-type display device, such as a liquid crystal panel or an organic electro luminescence (EL) panel, and displays a moving image or a still image captured by the solid-state image sensor 202. The recording unit 206 records the moving image or the still image captured by the solid-state image sensor 202 on a recording medium, such as a hard disk or a semiconductor memory.

The operation unit 207 issues operation commands for various functions of the image-capturing device 200 on the basis of the operations of a user. The power source unit 208 appropriately supplies various power supplies serving as operation power supplies for the DSP circuit 203, the frame memory 204, the display unit 205, the recording unit 206, and the operation unit 207 to these supply targets.

As described above, using the solid-state image sensor 100 having the above-mentioned structure of the pixel array region 1 as the solid-state image sensor 202 can suppress dark currents and image quality deterioration, for example. Moreover, an increased S/N ratio and a high dynamic range can be achieved. Accordingly, high image quality can be achieved in the captured image in the image-capturing device 200, such as a video camera, a digital still camera, and further a camera module for a mobile device, including a mobile phone.

### Usage Example of Image Sensor

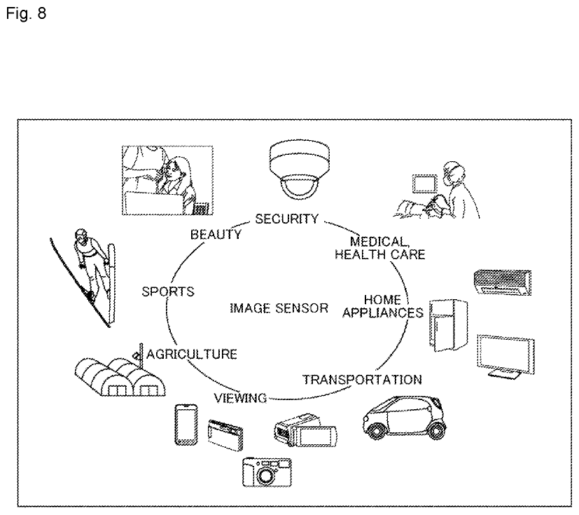

FIG. 8 is a diagram illustrating an example of how the image sensor including the solid-state image sensor 100 is used.

An image sensor including the above-mentioned solid-state image sensor 100 can be used in various cases for sensing light, such as visible light, infrared light, ultraviolet light, and X-ray, as will be described later.
Devices that capture images used for viewing, such as digital cameras and mobile devices with camera functions
Devices used for transportation, such as in-vehicle sensors that capture front, rear, surrounding, and interior view images of automobiles, monitoring cameras that monitor traveling vehicles and roads, or ranging sensors that measure the distance between vehicles, for safe driving such as automatic stop, recognition of a driver's condition, and the like
Devices used for home appliances such as TVs, refrigerators, and air conditioners in order to capture an image of a user's gesture and perform device operations in accordance with the gesture
Devices used for medical treatment and health care, such as endoscopes and devices that perform angiography by receiving infrared light
Devices used for security, such as monitoring cameras for crime prevention and cameras for personal authentication
Devices used for beauty, such as a skin measuring device that captures images of the skin and a microscope that captures images of the scalp
Devices used for sports, such as action cameras and wearable cameras for sports applications
Devices used for agriculture, such as cameras for monitoring the conditions of fields and crops

### 6. Exemplary Application to Moving Body

The technique according to the present disclosure (the present technique) can be applied to various products. For example, the technique according to the present disclosure may be realized as a device equipped in any type of moving body, such as an automobile, an electric vehicle, a hybrid electric vehicle, a motorcycle, a bicycle, a personal mobility device, an airplane, a drone, a ship, and a robot.

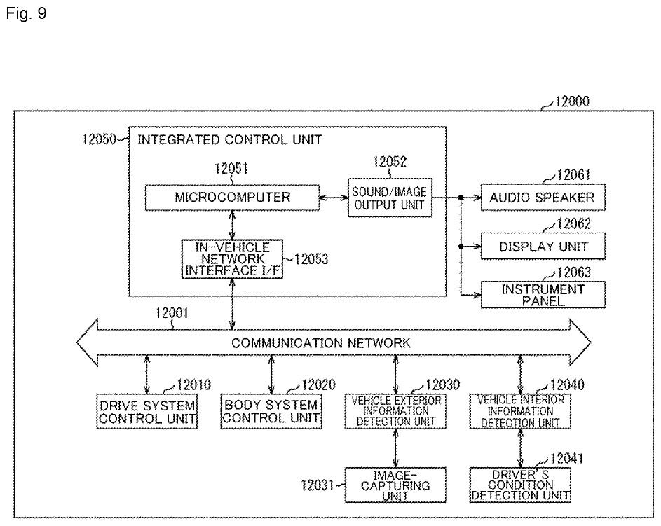

FIG. 9 is a block diagram illustrating a schematic configuration example of a vehicle control system, which is an example of a moving body control system to which the technique according to the present disclosure can be applied.

The vehicle control system 12000 includes a plurality of electronic control units connected thereto via a communication network 12001. In the example illustrated in FIG. 9, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound/image output unit 12052, and an in-vehicle network interface (I/F) 12053 are illustrated.

The drive system control unit 12010 controls the operation of an apparatus related to a drive system of a vehicle according to various programs. For example, the drive system control unit 12010 functions as a driving force generator for generating a driving force of a vehicle, such as an internal combustion engine or a driving motor, a driving force transmission mechanism for transmitting a driving force to wheels, a steering mechanism for adjusting a turning angle of a vehicle, and a control apparatus, such as a braking apparatus that generates a braking force of a vehicle.

The body system control unit 12020 controls the operation of various devices mounted in the vehicle body according to various programs. For example, the body system control unit 12020 functions as a control device of a keyless entry system, a smart key system, a power window device, or various lamps, such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, a lamp, and the like, of the vehicle.

The vehicle exterior information detection unit 12030 detects information on the outside of the vehicle having the vehicle control system 12000 mounted thereon. For example, an image-capturing unit 12031 is connected to the vehicle exterior information detection unit 12030. The vehicle exterior information detection unit 12030 causes the image-capturing unit 12031 to capture an image of the outside of the vehicle and receives the captured image. The vehicle exterior information detection unit 12030 may perform object detection processing or distance detection processing for people, cars, obstacles, signs, and letters on the road on the basis of the received image.

The image-capturing unit 12031 is an optical sensor that receives light and outputs an electrical signal according to the amount of the received light. The image-capturing unit 12031 can also output the electrical signal as an image or ranging information. In addition, the light received by the image-capturing unit 12031 may be visible light or invisible light, such as infrared light.

The vehicle interior information detection unit 12040 detects information on the inside of the vehicle. For example, a driver's condition detection unit 12041 that detects a driver's condition is connected to the vehicle interior information detection unit 12040. The driver's condition detection unit 12041 includes, for example, a camera that captures an image of a driver, and the vehicle interior information detection unit 12040 may calculate the degree of fatigue or concentration of the driver or may determine whether or not the driver is dozing on the basis of detection information inputted from the driver's condition detection unit 12041.

The microcomputer 12051 can calculate a control target value of the driving force generation device, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like, in which autonomous travel is performed without depending on the operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 on the basis of the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound/image output unit 12052 transmits an output signal of at least one of sound and an image to an output device capable of visually or audibly notifying a passenger or the outside of the vehicle of information. In the example of FIG. 9, an audio speaker 12061, a display unit 12062, and an instrument panel 12063 are illustrated as examples of the output device. The display unit 12062 may include at least one of an on-board display and a head-up display, for example.

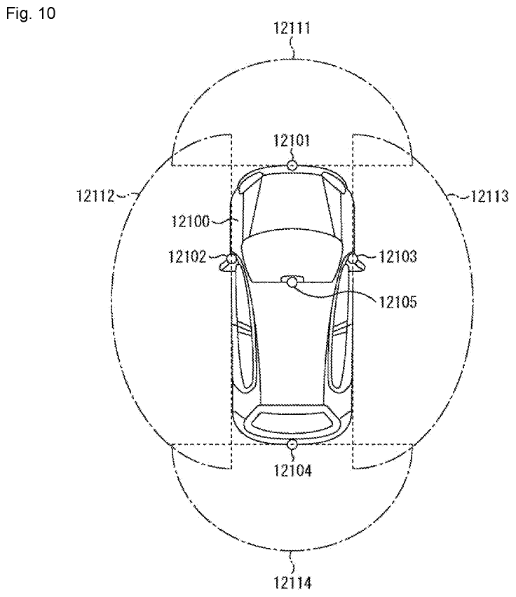

FIG. 10 is a diagram illustrating an example of the installation position of the image-capturing unit 12031.

In FIG. 10, a vehicle 12100 includes image-capturing units 12101, 12102, 12103, 12104, and 12105 as the image-capturing unit 12031.

The image-capturing units 12101, 12102, 12103, 12104, and 12105 are provided at positions such as a front nose, side-view mirrors, a rear bumper, a back door, and an upper portion of a windshield in a vehicle interior of the vehicle 12100, for example. The image-capturing unit 12101 provided on the front nose and the image-capturing unit 12105 provided in the upper portion of the windshield in the vehicle interior mainly acquire images of the front of the vehicle 12100. The image-capturing units 12102 and 12103 provided on the side-view mirrors mainly acquire images of a lateral side of the vehicle 12100. The image-capturing unit 12104 provided on the rear bumper or the back door mainly acquires images of the rear of the vehicle 12100. Front view images acquired by the image-capturing units 12101 and 12105 are mainly used to detect preceding vehicles, pedestrians, obstacles, traffic lights, traffic signs, lanes, and the like.

FIG. 10 illustrates an example of the image-capturing ranges of the image-capturing units 12101 to 12104. An image-capturing range 12111 indicates an image-capturing range of the image-capturing unit 12101 provided at the front nose, image-capturing ranges 12112 and 12113 respectively indicate the image-capturing ranges of the image-capturing units 12102 and 12103 provided at the side-view mirrors, and an image-capturing range 12114 indicates the image-capturing range of the image-capturing unit 12104 provided at the rear bumper or the back door. For example, by superimposing image data captured by the image-capturing units 12101 to 12104, it is possible to obtain a bird's-eye view image viewed above the vehicle 12100.

At least one of the image-capturing units 12101 to 12104 may have a function for obtaining distance information. For example, at least one of the image-capturing units 12101 to 12104 may be a stereo camera constituted by a plurality of image sensors or may be an image-capturing element with pixels for phase difference detection.

For example, the microcomputer 12051 can extract, particularly, the closest three-dimensional object on a path along which the vehicle 12100 is traveling, which is a three-dimensional object traveling at a predetermined speed (for example, 0 km/h or higher) in the substantially same direction as the vehicle 12100, as a preceding vehicle by acquiring the distance to each of three-dimensional objects in the image-capturing ranges 12111 to 12114 and temporal change of this distance (a relative speed with respect to the vehicle 12100) on the basis of the distance information obtained from the image-capturing units 12101 to 12104. Furthermore, the microcomputer 12051 can set an inter-vehicle distance which should be secured in front of the vehicle in advance with respect to the preceding vehicle and can perform automated brake control (also including following stop control) or automated acceleration control (also including following start control). In this way, it is possible to perform cooperative control for the purpose of automated driving or the like in which a vehicle autonomously travels without depending on the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the image-capturing units 12101 to 12104 and can use the three-dimensional data to perform automated avoidance of obstacles. For example, the microcomputer 12051 differentiates the surrounding obstacles of the vehicle 12100 into obstacles that can be viewed by the driver of the vehicle 12100 and obstacles that are difficult to view. Then, the microcomputer 12051 determines a collision risk indicating the degree of risk of collision with each obstacle, and when the collision risk is equal to or higher than a set value and there is a possibility of collision, an alarm is outputted to the driver through the audio speaker 12061 or the display unit 12062, forced deceleration or avoidance steering is performed through the drive system control unit 12010, and thus it is possible to perform driving support for collision avoidance.

At least one of the image-capturing units 12101 to 12104 may be an infrared camera that detects infrared rays. For example, the microcomputer 12051 can recognize a pedestrian by determining whether a pedestrian exists in the captured image of the image-capturing units 12101 to 12104. Such pedestrian recognition is performed by, for example, a procedure in which feature points in the captured images of the image-capturing units 12101 to 12104 as infrared cameras are extracted and a procedure in which pattern-matching processing is performed on a series of feature points indicating an outline of an object to determine whether or not the object is a pedestrian. When the microcomputer 12051 determines that there is a pedestrian in the captured images of the image-capturing units 12101 to 12104 and the pedestrian is recognized, the sound/image output unit 12052 controls the display unit 12062 so that a rectangular outline for emphasis be superimposed and displayed with the recognized pedestrian. In addition, the sound/image output unit 12052 may control the display unit 12062 so that an icon indicating a pedestrian or the like can be displayed at a desired position.

An example of a vehicle control system to which the technique according to the present disclosure can be applied has been described above. The technique according to the present disclosure can be applied to the image-capturing unit 12031 among the configurations described above. Specifically, an image sensor (e.g., the solid-state image sensor 100) with a structure of the pixel array region 1 described above can be applied as the image-capturing unit 12031. By applying the technique according to the present disclosure to the image-capturing unit 12031, a clearer captured image can be obtained, or distance information can be obtained while compactizing the device. In addition, using the obtained captured images and distance information, driver's fatigue can be reduced and increase driver and vehicle safety.

The technique of the present disclosure can be applied not only to solid-state image sensors that detect the distribution of the incident light amount of light with wavelengths within the visible region and a short infrared region and capture an image but also to any solid-state image sensor that captures an image of the distribution of the incident amount of infrared rays, X rays, or particles, or, in a broad sense, any solid-state image sensor (physical quantity distribution detection device), such as a fingerprint detection sensor, that detects the distribution of pressures, electrostatic capacities, or other physical quantities and captures an image.

The embodiments of the present disclosure are not limited to the above-described embodiments, and various modifications can be made without departing from the essential spirit of the technique of the present disclosure.

In the examples described above, a case where the charges (signal charges) treated as signals in the photoelectric conversion layer 13 are holes is described. Nevertheless, the technique according to the present disclosure may be applied to a solid-state image sensor using electrons as signal charges. In this case, conductive types of the semiconductor layer 11, the semiconductor substrate 31, or the like are reversed, and the positive and negative of the bias voltage applied are reversed.

For example, a combination of all or part of the plurality of embodiments described above may be employed.

The advantageous effects described in the present specification are merely exemplary and are not limited, and other advantageous effects of those described in the present specification may be achieved.

The technique of the present disclosure can be configured as follows.

(1)

A solid-state image sensor, including:
a photoelectric conversion layer containing a compound semiconductor;
pixel electrodes that take out an electric charge generated in the photoelectric conversion layer for each pixel; and
a pixel separation portion disposed between the pixel electrodes of each pixel.
   (2)

The solid-state image sensor according to the above (1), wherein
the pixel electrodes are formed so that the impurity concentration gradually decreases toward the photoelectric conversion layer.
   (3)

The solid-state image sensor according to the above (1) or (2), wherein
the pixel separation portion has a substantially T-shaped sectional structure including a separation wall that divides the pixel electrodes of each pixel and a plane portion that expands in a plane direction.
   (4)

The solid-state image sensor according to any one of the above (1) to (3), wherein
the pixel electrodes are formed by a diffused region of a P-type impurity.
   (5)

The solid-state image sensor according to any one of the above (1) to (4), wherein
the pixel electrodes are formed in a same layer as the pixel separation portion.
   (6)

The solid-state image sensor according to any one of the above (1) to (5), wherein
the pixel separation portion is composed of an oxide film or a metal film.
   (7)

The solid-state image sensor according to any one of the above (1) to (6), including
a pixel array region at least having
a first pixel that outputs the electric charge taken out from the pixel electrodes as a signal, and
a second pixel that discharges the electric charge taken out from the pixel electrodes.
   (8)

The solid-state image sensor according to the above (7), wherein
the pixel electrodes of the second pixel each have a planer region formed to be smaller than a planer region of the pixel electrodes of the first pixel.
   (9)

The solid-state image sensor according to the above (7) or (8), wherein
the pixel separation portion of the second pixel has a planer region formed to be larger than a planer region of the pixel separation portion of the first pixel.
   (10)

A method for manufacturing a solid-state image sensor including:
forming a pixel separation portion at a pixel boundary between a light incidence surface and an opposite surface of a photoelectric conversion layer containing a compound semiconductor, and
forming a pixel electrode that takes out an electric charge generated in the photoelectric conversion layer for each pixel in a pixel region inside the pixel separation portion in a plane direction.
   (11)

An electronic device including a solid-state image sensor that includes:
a photoelectric conversion layer containing a compound semiconductor;
pixel electrodes that take out an electric charge generated in the photoelectric conversion layer for each pixel; and
a pixel separation portion disposed between the pixel electrodes of each pixel.

### REFERENCE SIGNS LIST

1 Pixel array region
10 Sensor substrate
11 Semiconductor layer
12 Pixel electrode
13 Photoelectric conversion layer
14 Barrier layer
15 Upper electrode
16 Passivation film
17 Contact electrode
18 Passivation film
19 Pad electrode
20 Interlayer insulation film
21 High concentration region
22 Middle concentration region
23 Low concentration region
24 Pixel separation portion
24A Pixel separation plane portion
24B Pixel separation wall
30 Circuit board
31 Semiconductor substrate
32 Pad electrode
33 Contact electrode
34 Interlayer insulation film
100 Solid-state image sensor
102 Pixel
103 Pixel array region
200 Image-capturing device
202 Solid-state image sensor
Px Pixel
Py Pixel

1. A solid-state image sensor comprising:
a photoelectric conversion layer containing a compound semiconductor;
pixel electrodes that take out an electric charge generated in the photoelectric conversion layer for each pixel; and
a pixel separation portion disposed between the pixel electrodes of each pixel.

2. The solid-state image sensor according to claim 1, wherein
an impurity concentration in the pixel electrodes is formed so as to gradually decrease toward the photoelectric conversion layer.

3. The solid-state image sensor according to claim 1, wherein
the pixel separation portion has a substantially T-shaped sectional structure comprising a separation wall that divides the pixel electrodes of each pixel and a plane portion that expands in a plane direction.

4. The solid-state image sensor according to claim 1, wherein
the pixel electrodes are formed by a diffused region of a P-type impurity.

5. The solid-state image sensor according to claim 1, wherein
the pixel electrodes are formed in a same layer as the pixel separation portion.

6. The solid-state image sensor according to claim 1, wherein
the pixel separation portion is composed of an oxide film or a metal film.

7. The solid-state image sensor according to claim 1, comprising
a pixel array region at least having
a first pixel that outputs the electric charge taken out from the pixel electrodes as a signal, and
a second pixel that discharges the electric charge taken out from the pixel electrodes.

8. The solid-state image sensor according to claim 7, wherein
the pixel electrodes of the second pixel each have a planer region formed to be smaller than a planer region of the pixel electrodes of the first pixel.

9. The solid-state image sensor according to claim 7, wherein
the pixel separation portion of the second pixel has a planer region formed to be larger than a planer region of the pixel separation portion of the first pixel.

10. A method for manufacturing a solid-state image sensor, comprising:
forming a pixel separation portion at a pixel boundary between a light incidence surface and an opposite surface of a photoelectric conversion layer containing a compound semiconductor, and
forming a pixel electrode that takes out an electric charge generated in the photoelectric conversion layer for each pixel in a pixel region inside the pixel separation portion in a plane direction.

11. An electronic device comprising a solid-state image sensor that includes:
a photoelectric conversion layer containing a compound semiconductor;
pixel electrodes that take out an electric charge generated in the photoelectric conversion layer for each pixel; and
a pixel separation portion disposed between the pixel electrodes of each pixel.
